(19) United States
(12) Patent Application Publication
(10) Pub. No.: US 2025/0059674 A1
(43) Pub. Date: Feb. 20, 2025

(54) REDUCING ELECTRICAL ACTIVITY OF DEFECTS IN SILICON CARBIDE GROWN ON SILICON

(71) Applicant: Anvil Semiconductors Ltd, Cambridge, Cambridgeshire (GB)

(72) Inventor: Martin Steven Mark LAMB, Milton Keynes, Buckinghamshire (GB)

(21) Appl. No.: 18/720,734

(22) PCT Filed: Dec. 13, 2022
(86) PCT No.: PCT/GB2022/053188

§ 371 Date: Jun. 17, 2024

(30) Foreign Application Priority Data
Dec. 17, 2021 (GB) 2118422.1

(51) Int. Cl. C30B 25/16; C30B 25/18; C30B 29/36; H01L 21/02; H01L 29/16

(52) U.S. Cl. CPC C30B 25/165; C30B 25/18; C30B 29/36; H01L 21/02529; H01L 21/02576; H01L 21/02609; H01L 29/1608

(57) ABSTRACT

A method is provided for reducing the electrical activity of defects in a silicon carbide epitaxial layer grown on a silicon wafer, the method comprising reducing oxidation of silicon during growth of the silicon carbide epitaxial layer. We also describe a semiconductor structure comprising: a silicon wafer; and a silicon carbide epitaxial layer grown on the silicon wafer; wherein the silicon carbide epitaxial layer is doped with a precursor, the precursor being configured to reduce oxidation of silicon during growth of the silicon carbide epitaxial layer. Reducing the oxidation of silicon may advantageously reduce or prevent the preferential uptake of nitrogen at defects by reducing the formation of the intermediate species (i.e. silicon dioxide) in the reaction.

### FIELD

This disclosure relates to reducing the electrical activity of defects in a silicon carbide epitaxial layer grown on silicon by reducing oxidation of silicon during growth of the silicon carbide layer.

### BACKGROUND

3-step cubic silicon carbide (3c SiC) grown on silicon wafers has attracted considerable interest in recent years as a potential route to reducing the cost of high power and high voltage electronic devices by eliminating the need for costly SiC substrates. However, producing SiC layers of this polytype of sufficient quality to permit the manufacture of effective electronic devices on standard silicon substrates has proved elusive. Indeed, the limitations of the 3c SiC epitaxial layers produced are such that many groups have abandoned their attempts to grow the material on silicon in favour of producing a pseudo 3c SiC substrate which opens the way for the use of much higher growth temperatures which in turn should help to address the fundamental material quality issues. While this approach may eventually prove successful, it offers precious little advantage over the use of a 4H SiC substrate in cost terms and in the material quality of the layers produced is unlikely to be competitive with the more established 4H technology in the short term.

The primary inadequacy of 3c SiC epitaxial layers produced on silicon is that they contain significant numbers of extended planar defects such as stacking faults and microtwins which originate from the interface between the silicon substrate and the SiC layer. It is well-documented in the literature that these defects interact as the epitaxial layer grows and their density falls steeply in the first few microns of growth as they self-terminate. However, even after several tens of microns of epitaxy they reach a residual level of linear density of a few thousand per cm and thereafter there is no further improvement. No simple techniques suitable for volume manufacturing have been demonstrated for reducing their density still further while using a silicon substrate.

The literature suggests that the defects themselves are not necessarily a problem but it has been extensively reported that they are extremely electrically active, even in unintentionally doped material. Published data suggests that in lightly doped n-type material, the defects show an electrical conductivity higher than that presented by an n-type layer doped at 5E18 per cc. There is now published work that suggests that it is this electrical activity that contributes to the unacceptable leakage currents that flow in devices fabricated in this material.

Much work has been conducted on the underlying cause of the electrical activity of the extended defects and the general consensus in the literature is that it is caused by the preferential incorporation of nitrogen around the defects during growth. The inventors' own work supports this thesis with nitrogen concentrations measured by SIMS showing a notable decrease despite a constant feed of dopant precursor during growth, an observation consistent with the reduction in decorated defect density. Little work has been reported on attempting to explain the mechanism for the preferential incorporation of the dopant at the defects or indeed attempting to change their electrical behaviour. As mentioned above, the primary focus has been on eliminating them altogether with the chosen approaches likely to negate any cost advantages conferred by using a silicon substrate.

### SUMMARY

The present disclosure achieves a reduction in the electrical activity of defects in silicon carbide (SiC) grown on silicon by reducing, or preventing, the oxidation of silicon during growth of a silicon carbide epitaxial layer. It will be understood that “reducing the oxidation of silicon” may mean reducing the amount of silicon that is oxidised during growth of the silicon carbide epitaxial layer. The silicon, the oxidation of which is reduced, could include e.g. any silicon that is present during the growth process, including silicon in the substrate, in the grown SiC layer itself, or elsewhere (such as silicon present in an epitaxial growth apparatus).

As discussed in the present disclosure, without wishing to be bound by theory, n-type dopants in SiC, (e.g. nitrogen in the examples described in the present disclosure) are preferentially incorporated at defects that form in SiC grown on Si. Defects may include extended planar defects such as stacking faults and microtwins. Without wishing to be bound by theory, experimental evidence described in the present disclosure indicates that the incorporation of nitrogen at the defects is not a direct process, but rather takes place via a reaction between silicon and oxygen to form an intermediate species (i.e. silicon dioxide), which subsequently undergoes carbothermal reduction by nitrogen during epitaxial growth.

It would therefore be advantageous to reduce or prevent the preferential uptake of nitrogen at defects by preventing the oxidation of silicon during epitaxial growth to prevent (or reduce) formation of the intermediate species (i.e. silicon dioxide) in the reaction. Reducing or preventing the oxidation of silicon during epitaxial growth of the silicon carbide layer would advantageously reduce the electrical activity of the defects, while enabling the fabrication of devices based on SiC grown on Si that is simple and cheap to produce without necessitating the elimination of the defects themselves. However, to the inventors' knowledge, no work has considered controlling oxygen (e.g. reducing or preventing oxidation of silicon) during epitaxial growth of silicon carbide on silicon for this purpose to date.

According to the present disclosure, epitaxial growth may comprise reacting gases, for example in a reactor, to produce silicon carbide.

We describe herein a method for reducing the electrical activity of defects in a silicon carbide epitaxial layer grown on a silicon wafer, the method comprising reducing oxidation of silicon during growth of the silicon carbide epitaxial layer.

We also describe herein a method for manufacturing a silicon carbide epitaxial layer, the method comprising: providing a silicon wafer; growing a silicon carbide epitaxial layer on the silicon wafer; and reducing oxidation of silicon during growth of the silicon carbide epitaxial layer.

Reducing or preventing oxidation of silicon during growth of silicon carbide advantageously blocks the uptake of nitrogen (or another dopant) at the defects by preventing the formation of the intermediate species required in the reaction, thus reducing the electrical activity of defects in the silicon carbide epitaxial layer and enabling the use of silicon carbide grown on silicon in devices.

Reducing oxidation of silicon may comprise introducing a precursor during epitaxial growth of the silicon carbide epitaxial layer, wherein the precursor is configured such that oxygen reacts preferentially with the precursor over the silicon.

Introducing a precursor configured such that oxygen reacts preferentially with the precursor over the silicon advantageously prevents the reaction between oxygen and silicon, thus preventing the formation of the intermediate species and so preventing the incorporation of nitrogen (or another dopant) in the defects.

In some examples, the precursor may comprise any of aluminium, magnesium, titanium, and/or calcium. For example, the precursor may comprise a metalorganic compound such as trimethyl aluminium.

In some examples, the precursor forms an energy state deep in the bandgap of the silicon carbide. In some examples, a precursor that forms an energy state deep in the bandgap may be preferable to a shallow acceptor to prevent undesired p-doping of the silicon carbide.

In some examples, the methods according to the present disclosure may comprise introducing an n-type dopant during growth of the silicon carbide epitaxial layer.

Advantageously, n-type silicon carbide can be produced by epitaxial growth on silicon, while also preventing the incorporation of the n-type dopant at defects by introducing the precursor.

In some examples, the n-type dopant may be introduced at the same time as the precursor. Introducing the precursor and the n-type dopant at the same time during growth may advantageously prevent the unintentional formation of a p-type layer of silicon carbide. This may be particularly advantageous where a shallow acceptor, such as aluminium, is used as the precursor.

In some examples, the n-type dopant is nitrogen.

In some examples, the precursor may be introduced at a level suitable to result in a doping concentration of the silicon carbide by the precursor of less than E17 per cc.

In some examples, the precursor may be introduced at a level suitable to result in a doping concentration of the silicon carbide by the precursor of less than E17 per cc.

It will be understood that the level at which the precursor is introduced may be varied by e.g. adjusting a gas or atomic flow during the epitaxial growth process.

In some examples, growth of the silicon carbide epitaxial layer comprises reacting gases (for example in a reaction chamber or reaction zone); and the method may further comprise using a scavenger plate or tube to remove oxygen from the gases prior to reacting the gases (i.e. prior to the arrival of the gases in the reaction chamber or reaction zone). A scavenger plate may comprise e.g. a hot metal (e.g. titanium) plate or tube to remove oxygen from the gases.

In some examples, the silicon carbide epitaxial layer comprises a 3-step cubic silicon carbide (3C—SiC).

We also describe herein a semiconductor structure comprising: a silicon wafer; and a silicon carbide epitaxial layer grown on the silicon wafer; wherein the silicon carbide epitaxial layer is doped with a precursor, the precursor being configured to reduce oxidation of silicon during growth of the silicon carbide epitaxial layer.

A SiC-on-Si semiconductor structure in which oxidation of silicon is reduced during growth according to the present disclosure advantageously exhibits reduced electrical activity of defects, and is therefore suitable for use in semiconductor devices without requiring the use of more complex and costly structures in which defects themselves are reduced or eliminated.

In some examples, the silicon carbide layer is n-type.

In some examples, the silicon carbide layer is nitrogen-doped.

During growth of a semiconductor structure according to the present disclosure, the precursor advantageously reduces or prevents oxidation of silicon, thus preventing the formation of the intermediate species (i.e. silicon dioxide) required for the reaction that would otherwise lead to the incorporation of the n-type dopant (e.g. nitrogen) at defects.

In some examples, a doping concentration of the precursor in the silicon carbide epitaxial layer is less than E17 per cc.

In some examples, a doping concentration of the precursor in the silicon carbide epitaxial layer is less than E16 per cc.

In some examples, the silicon carbide epitaxial layer comprises a 3-step cubic silicon carbide (3C—SiC).

In some examples, the precursor comprises any of: aluminium; titanium; magnesium; and/or calcium.

We also describe herein a semiconductor device comprising a semiconductor structure as described herein.

### BRIEF DESCRIPTION OF THE DRAWINGS

FIG. 1 shows a cross-sectional scanning capacitance microscopy image of a 3c SiC epitaxial structure consisting of a heavily aluminium doped p-type layer on top of approximately 4 μm of lightly nitrogen doped n-type material on top of a heavily nitrogen doped buffer layer all grown on an n+ silicon substrate (credit: Prof. R. A. Oliver, University of Cambridge);

FIG. 2 shows further scanning capacitance microscopy data zooming in on the lightly nitrogen doped n-type region of the same sample shown in FIG. 1 (credit: Prof. R. A. Oliver, University of Cambridge);

FIG. 3 illustrates a flow diagram of an example of a method according to the present disclosure;

FIG. 4 schematically illustrates a semiconductor structure according to the present disclosure; and

FIG. 5 schematically illustrates a vertical power semiconductor transistor 100 in the form of an insulated gate bipolar transistor (IGBT).

### DETAILED DESCRIPTION

### Experimental Details

In the course of some experimental work looking to produce an epitaxially produced p+n diode, Scanning Capacitance Microscopy (SCM, a conductive atomic force microscopy, AFM, technique), revealed that in the lightly doped (low E16 per cc) n-layer of the diode, the extended defects showed very high contrast, consistent with other data reported in the literature and consistent with the preferential incorporation of the dopant around the defects. However, in the p-type region of the structure, no such contrast was evident and the defects were not visible in the conductive image suggesting that the extreme n-type conductivity had been successfully overdoped without any compensation. CV profiling to extract the carrier concentration and SIMS suggested that the aluminium dopant was indeed close to 100% active in the layer. The p-layer which was doped with aluminium at around 5E18 per cc was electrically uniform at the microscopic level with no evident variations locally around the defects.

On the strength of this, a second set of samples were grown, this time with the aluminium doping reduced to around 1E17 per cc. Since the n-type background was thought to be around mid E15 per cc, it was thought that with the disparity between the electron and hole mobility (e.g. approximately 500-800 cm²/(Vs) and less than 10 cm²/(Vs), respectively), the layer would be compensated and might actually show as n-type. SCM was performed and the layer was solidly p-type. It also showed no evidence of contrast around the stacking faults and was evidently much more uniform than the usual n-type material. In short, the evidence is that aluminium does not preferentially incorporate around the stacking faults in the way that nitrogen does, even in unintentionally doped layers. The other implication is that the aluminium dopant fundamentally affects how the background n-type impurities incorporate.

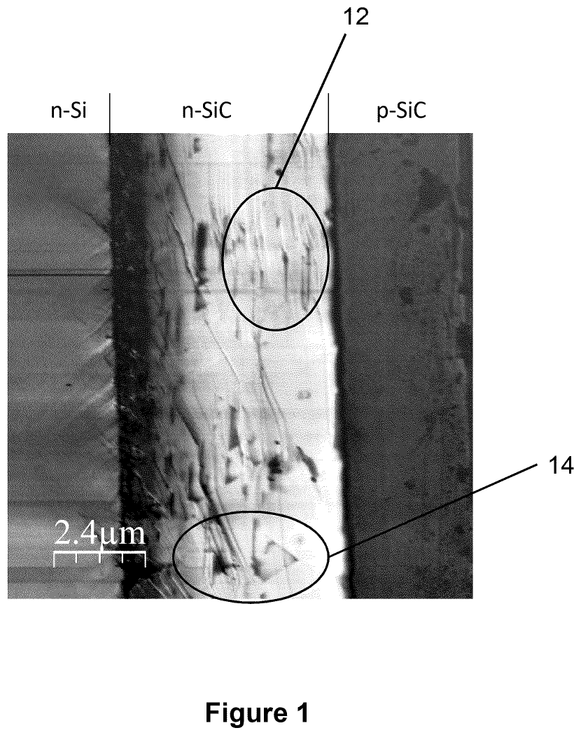

FIG. 1 shows a cross-sectional scanning capacitance microscopy image of a 3c SiC epitaxial structure consisting of a heavily aluminium doped p-type layer on top of approximately 4 μm of lightly nitrogen doped n-type material on top of a heavily nitrogen doped buffer layer all grown on an n+ silicon substrate. There are a number of darker features in the lightly nitrogen doped region some 12 of which are due to the topography of the sample surface and others 14 which are linear and parallel to the interface/surface or triangular and/or inclined at close to 60° to the interface with the silicon that are likely to be related to crystallographic defects. In FIG. 1 the defect related features are not obvious in the heavily aluminium doped p-type region.

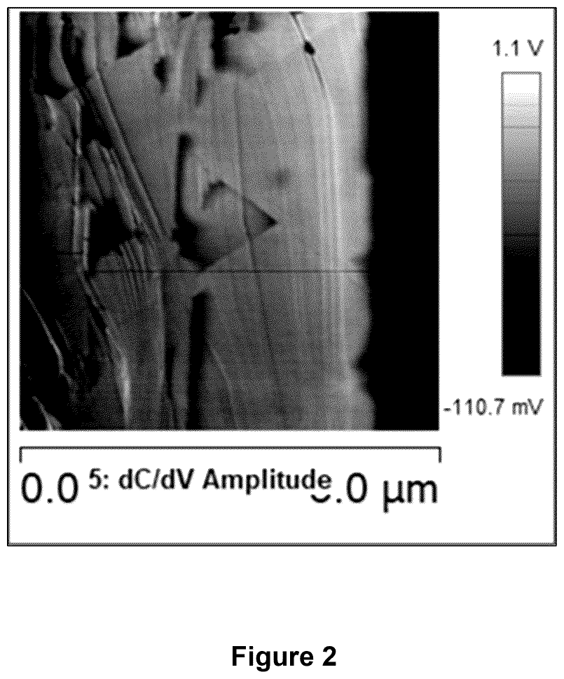

FIG. 2 shows further scanning capacitance microscopy data zooming in on the lightly nitrogen doped n-type region of the same sample shown in FIG. 1. It is noticeable that in this case, there are multiple dark features at approximately 60° angles, characteristic of stacking faults aligned along crystallographic directions. Under the conditions used for these measurements, the darker the region of the image, the higher the carrier concentration and electrical conductivity of the material in that area of the sample. This data suggests that the stacking faults and planar defects are much more conductive than the background material, consistent with other reports in the literature and clearly illustrating the effect that the current invention is aimed at addressing.

### DISCUSSION

Clearly, the use of aluminium as a dopant produces layers that are microscopically much more electrically homogeneous than those doped with nitrogen with no evidence of preferential incorporation around the defects. This raises two key questions: why is that the case and can this be used to improve the quality of nitrogen doped layers?

Dealing with the first point, it is worth considering the doping of layers with nitrogen. The literature argues that nitrogen gas is generally used as the dopant precursor of choice since it is less reactive than the alternatives such as ammonia or hydrazine. However, given that nitrogen is reported to incorporate preferentially and extensively even when it is picked up from the reactor background in unintentionally doped layers, it is clear that the incorporation mechanism is highly effective in the vicinity of the defects. Looking at the reaction between silicon and nitrogen, although they do combine the reaction is said to be slow even at elevated temperatures. It is perhaps plausible that the reaction would occur preferentially at the defects where the usual crystal structure and interatomic bonds are disrupted and silicon may be bonded to silicon rather than to carbon. However the fact that the reaction is reportedly slow suggests that the direct incorporation of nitrogen is not likely to be the origin of these observations. Further examination of the possibilities suggests that the reaction can be significantly accelerated if it is a carbothermal reduction process as follows:

3 S:O₂+6 C+2 N₂→Si₃N₄+6 CO

This reaction is said to proceed very rapidly at temperatures around 1400° C. which is close to the growth temperature here. While the inventors are not arguing that they are producing silicon nitride, it is clear that the carbothermal reduction of silicon dioxide by nitrogen is a favourable reaction and may account for the observed uptake of nitrogen.

Such a mechanism might fit with the observed uptake of nitrogen in unintentionally doped layers since if nitrogen is present as a background contaminant from adsorbed air, then it is likely that oxygen (possibly from water vapour or adsorbed air) might also be present. Also, since the reaction of oxygen with silicon is rapid that might very plausibly occur close to the defects for the reasons highlighted above. A mechanism where oxidation occurs quickly at the defects followed by a rapid carbothermal reduction to incorporate nitrogen could account for the observations.

If this is the case and there is oxygen present in the reactor ambient it is worth looking at which chemical compounds might plausibly be formed on the wafer surface. At the elevated growth temperatures employed here, the Ellingham diagram suggests that without the introduction of other materials, any oxygen will indeed bind to “free” silicon to form silicon dioxide in preference to any other oxygen containing species. This will then be reduced through the carbothermal process above. This is consistent with the inventors' observations.

What happens when we introduce an aluminium dopant precursor?Again looking at the Ellingham diagram, any oxygen will be taken up by the aluminium to form aluminium trioxide in preference to silicon dioxide—the Ellingham diagram shows that aluminium will reduce silicon dioxide. In this instance, due to the heat of formation of the alumina and the reaction temperature, the carbothermal reduction is not possible so any nitrogen in the system will remain in the ambient and potentially react very slowly with the substrate. It seems likely therefore that the presence of the aluminium precursor not only allows the doping of the grown layer with aluminium but also blocks the (preferential) uptake of nitrogen by preventing the oxidation of silicon in the system to form the required intermediate species—silicon dioxide—in the reaction. This would account for the apparently low levels of compensation observed in aluminium doped layers and the absence of any preferential incorporation of dopant and their improved microscopic electrical homogeneity.

### Implications

If this hypothesis is correct then we may have a route to managing the electrical activity of the extended defects in 3c SiC on silicon substrates. The key appears to be controlling the oxygen in the reactor atmosphere to prevent preferential oxidation at the defects during the growth process. From the Ellingham diagram, introducing a precursor into the reactor that will lock up the background oxygen ought to deliver positive results. The candidates that would prevent the oxidation of silicon would appear to be aluminium, titanium, magnesium and calcium all of which would oxidise in preference to the silicon.

Both aluminium and magnesium ought to be available in suitable forms since both are used extensively in either SiC or III-V epitaxy. Aluminium is a shallow acceptor in SiC and so exploring the level required to prevent the preferential uptake of nitrogen without forming a lightly p-doped layer will be important. It may be necessary to feed both aluminium to knock out the oxygen at a low level but also to re-dope with nitrogen at the same time. The starting point would be to look at running aluminium at a level that would give rise to a doping level of a few E15 per cc in the SiC while running the nitrogen feed as usual. Magnesium forms a deep level in the bandgap and may be preferable and would certainly be worth considering. Titanium forms a level in the conduction band.

Beyond the use of a gas phase precursor it is possible that with its high melting point, the use of a hot, solid titanium scavenger plate or tube to “clean” up the gases prior to the reaction zone might be viable. It will be appreciated that the scavenger plate or tube would need to be configured to avoid it becoming coated with SiC and rendered ineffective. Furthermore, it will be appreciated that a scavenger plate or tube is a plate or tube comprising a material (such as a metal, e.g. titanium) that reacts with oxygen from the ambient atmosphere in the reactor. A scavenger plate or tube may therefore be placed in the hot region of the reactor to remove oxygen from the gases being supplied to effect the epitaxy. In use, the hot gases may pass over a scavenger plate, and/or through a scavenger tube, and any oxygen in said hot gases may react with the scavenger plate or tube as described herein.

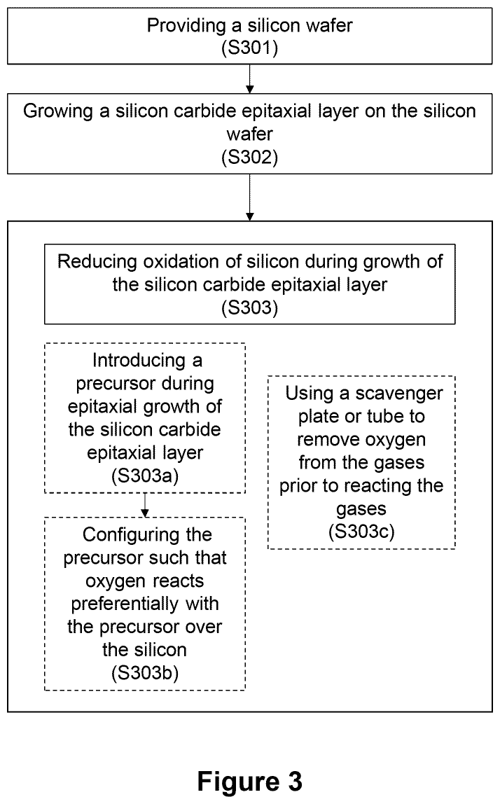

FIG. 3 illustrates an example of a method according to the present disclosure. In the example method according to FIG. 3, a silicon wafer is provided in a first step S301. In a second step S302, a silicon carbide epitaxial layer is grown on the silicon carbide wafer. A third step S303 of the example method comprises reducing the oxidation of silicon during growth of the silicon carbide epitaxial layer. As shown in optional steps S303a and S303b; and S303c, reducing oxidation of silicon during growth of the silicon carbide epitaxial layer may comprise: introducing a precursor during growth of the silicon carbide epitaxial layer S303a and configuring the precursor such that oxygen reacts preferentially with the precursor over the silicon S303b; and/or reducing oxidation of silicon during growth of the silicon carbide epitaxial layer, e.g. where growth of the silicon carbide epitaxial layer comprises reacting gases, may comprise using a scavenger plate or tube to remove oxygen from the gases prior to reacting the gases S303c.

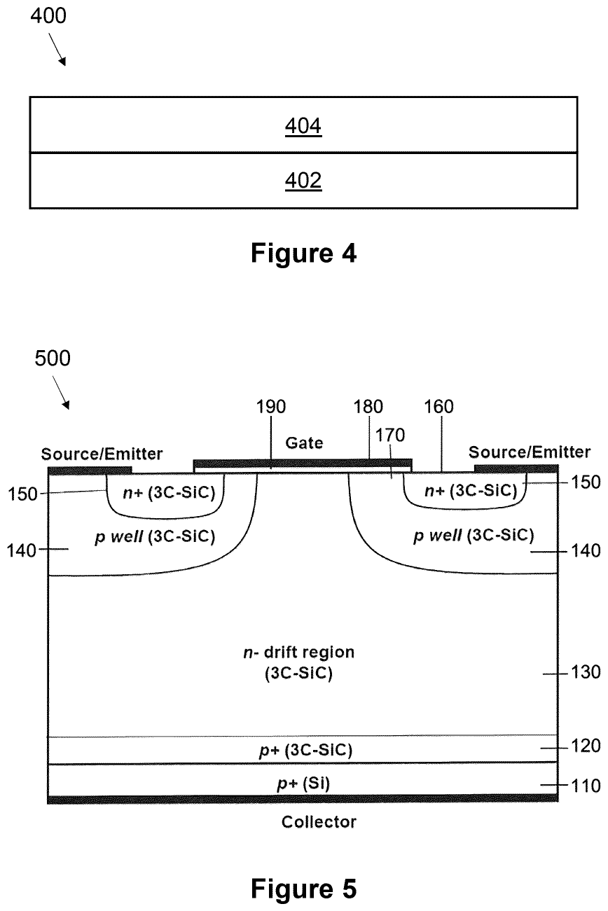

FIG. 4 schematically illustrates a semiconductor structure 400 comprising a silicon wafer 402 and a SiC epitaxial layer 404 grown on the silicon wafer 402 using the process described in the embodiments above in the present disclosure, i.e. wherein oxidation of silicon is reduced during growth of the SiC epitaxial layer 404. For example, the SiC epitaxial layer 404 may doped with a precursor, the precursor being configured to reduce oxidation of silicon during growth of the SiC epitaxial layer 404, and/or the SiC epitaxial layer 404 may be grown by reacting gases, and growing the SIC epitaxial layer 404 may comprise using a scavenger plate or tube to remove oxygen from the gases prior to reacting the gases. Reducing the oxidation of silicon during growth of the SiC epitaxial layer 404 may advantageously block the uptake of nitrogen (or another dopant) at the defects by preventing the formation of the intermediate species required in the reaction, thus reducing the electrical activity of defects in the SiC epitaxial layer 404. A semiconductor device incorporating the semiconductor structure 400 may therefore exhibit improved performance compared to a semiconductor device comprising a semiconductor structure comprising a SiC epitaxial layer wherein oxidation of silicon is not reduced during its growth. The SiC epitaxial layer 404 may be a 3-step cubic silicon carbide (3c SiC) layer. The SiC epitaxial layer 404 may be n-type.

FIG. 5 illustrates a vertical power semiconductor transistor 500 in the form of an insulated gate bipolar transistor (IGBT), as an example of a semiconductor device according to the present disclosure. The transistor 500 comprises a p-type silicon substrate 110, a first 3-step cubic silicon carbide (3c SiC) epitaxial layer 120, and a second 3c SiC epitaxial layer 130. It will be understood that, for the purposes of the example illustrated in FIG. 5, both the first 120 and second 130 3c SiC epitaxial layers may be considered as grown on the silicon substrate 110. In this example, the silicon carbide epitaxial layers 120, 130 include a heavily-doped p-type layer 120 which is supported on the p-type silicon substrate 110, and a lightly-doped n-type layer 130 which provides a drift region and which is supported on the p-type silicon carbide layer 120. The first epitaxial layer 120 provides a p-type collector. P-type wells 140 at the surface 160 of the epitaxial layer 130 provide body regions 140. N-type wells 150 within the p-type wells 140 provide contact regions and provide emitters. The body region 140 and the contact region 150 can be formed using 3C—SiC material. A channel 170 is formed beneath a gate 180 which is separated using a gate dielectric layer 190. All these layers comprise 3C—SiC layers. At least the second epitaxial layer 130 is grown using the process described in the embodiments above in the present disclosure, i.e. wherein oxidation of silicon is reduced during growth of the silicon carbide epitaxial layer 130. For example, the silicon carbide epitaxial layer 130 may doped with a precursor, the precursor being configured to reduce oxidation of silicon during growth of the silicon carbide epitaxial layer 130, and/or the silicon carbide epitaxial layer 130 may be grown by reacting gases, and growing the epitaxial layer 130 may comprise using a scavenger plate or tube to remove oxygen from the gases prior to reacting the gases. Reducing the oxidation of silicon during growth of the epitaxial layer 130 may advantageously block the uptake of nitrogen (or another dopant) at the defects by preventing the formation of the intermediate species required in the reaction, thus reducing the electrical activity of defects in the silicon carbide epitaxial layer 130 and improving performance of the transistor 500.

Although in FIG. 5 the example of an IGBT is presented, it would be apparent to the skilled person that the present technique can be equally applicable to form other semiconductor devices and transistors, for example, diode, MOSFET, thyristor.

Although the present specification makes reference to the interface of the silicon substrate and 3C—SiC epitaxial layer, it would be appreciated that the technique may also be equally applicable to other poly types of SiC.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1.-24. (canceled)

25. A method for reducing the electrical activity of defects in a silicon carbide epitaxial layer grown on a silicon wafer, the method comprising reducing oxidation of silicon during growth of the silicon carbide epitaxial layer.

26. A method for manufacturing a silicon carbide epitaxial layer, the method comprising:
providing a silicon wafer;
growing a silicon carbide epitaxial layer on the silicon wafer; and
reducing oxidation of silicon during growth of the silicon carbide epitaxial layer.

27. A method according to claim 26, wherein reducing oxidation of silicon comprises:
introducing a precursor during epitaxial growth of the silicon carbide epitaxial layer; and
configuring the precursor such that oxygen reacts preferentially with the precursor over the silicon.

28. A method according to claim 27, wherein the precursor comprises any of: aluminium; titanium; magnesium; and/or calcium.

29. A method according to claim 27, wherein the precursor forms an energy state in the bandgap of the silicon carbide.

30. A method according to claim 27, further comprising introducing an n-type dopant during growth of the silicon carbide epitaxial layer.

31. A method according to claim 30, comprising introducing the n-type dopant at the same time as introducing the precursor.

32. A method according to claim 30, wherein the n-type dopant is nitrogen.

33. A method according to claim 27, comprising introducing the precursor at a level suitable to result in a doping concentration of the silicon carbide by the precursor of less than E17 per cubic centimetre.

34. A method according to claim 27, comprising introducing the precursor at a level suitable to result in a doping concentration of the silicon carbide by the precursor of less than E16 per cubic centimetre.

35. A method according to claim 26, wherein growth of the silicon carbide epitaxial layer comprises reacting gases; and
wherein the method further comprises using a scavenger plate or tube to remove oxygen from the gases prior to reacting the gases.

36. A method according to claim 26, wherein the silicon carbide epitaxial layer comprises 3-step cubic silicon carbide (3c SiC).

37. A method according to claim 26, wherein the defects comprise stacking faults, and/or microtwins.

38. A semiconductor structure comprising:
a silicon wafer; and
a silicon carbide epitaxial layer grown on the silicon wafer;
wherein the silicon carbide epitaxial layer is doped with a precursor, the precursor being configured to reduce oxidation of silicon during growth of the silicon carbide epitaxial layer.

39. A semiconductor structure according to claim 38, wherein the silicon carbide layer is n-type.

40. A semiconductor structure according to claim 38, wherein the silicon carbide layer is nitrogen-doped.

41. A semiconductor structure according to claim 38, wherein a doping concentration of the precursor in the silicon carbide epitaxial layer is less than E17 per cubic centimetre or less than E16 per cubic centimetre.

42. A semiconductor structure according to claim 38, wherein the silicon carbide epitaxial layer comprises 3-step cubic silicon carbide (3c SiC).

43. A semiconductor structure according to claim 38, wherein the precursor comprises any of: aluminium; titanium; magnesium; and/or calcium.

44. A semiconductor device comprising the semiconductor structure of claim 38.
